(19) United States
(12) Patent Application Publication
(10) Pub. No.: US 2024/0250217 A1
(43) Pub. Date: Jul. 25, 2024

(54) Plug Regrowth for Micro LED Uniformity and Efficiency Improvement

(71) Applicant: Apple Inc., Cupertino, CA (US)

(72) Inventors: Xiaobin Xin, Sunnyvale, CA (US); Dmitry S Sizov, Cupertino, CA (US); Chi-Kang Li, San Diego, CA (US); Steve M Ting, Dublin, CA (US); Fang Ou, San Jose, CA (US); David P Bour, Cupertino, CA (US)

(21) Appl. No.: 18/408,137

(22) Filed: Jan. 9, 2024

Related U.S. Application Data
(60) Provisional application No. 63/481,238, filed on Jan. 24, 2023.

(51) Int. Cl. H01L 33/44; H01L 33/06; H01L 33/16

(52) U.S. Cl. CPC H01L 33/44; H01L 33/06; H01L 33/16

(57) ABSTRACT

Light emitting diodes with regrown semiconductor layers and methods of manufacture are described. In an embodiment, a light emitting diode includes a base structure including a first cladding layer and a pillar structure protruding from the base layer. The pillar structure includes a mesa structure and a second cladding layer that includes a plug portion that is laterally adjacent to a plurality of quantum well layers of the mesa structure.

### RELATED APPLICATIONS

This application claims the benefit of priority of U.S. Provisional Application No. 63/481,238 filed Jan. 24, 2023, which is incorporated herein by reference.

### BACKGROUND

### Field

Embodiments described herein relate to light emitting diodes (LEDs). More particularly embodiments relate to LED regrowth structures.

### Background Information

Inorganic semiconductor-based light emitting diodes (LED) may typically be fabricated from III-V or II-VI systems such as GaN/InGaN and InGaAlP systems. Generally, a vertical inorganic semiconductor-based micro LED may include a p-doped cladding layer for hole injection, an n-doped cladding layer for electron injection, and an active layer therebetween. The active layer may include one or more quantum well layers and barrier layers for example. In operation light is emitted as a result of recombination of holes and electrons in the quantum wells.

As LED dimensions are reduced to micro LED dimensions it has been observed that surface defect states created at micro LED sidewalls can lead to nonradiative recombination of holes and electrons, and hence a reduction in internal quantum efficiency (IQE) of the micro LEDs. In order to address these defect states, it has been proposed to passivate the micro LED sidewalls using techniques such as diffusion or regrowth.

### SUMMARY

LED structures and methods of manufacture are described in which regrown semiconductor layers are utilized to provide an avenue for sidewall carrier injection to the active layers of the LEDs. In accordance with embodiments, cavities are etched into a first cladding layer and/or active layer of a bulk LED substrate, followed by regrowth of plug portions. Pillar structures for the LEDs can then be etched, where sidewall injection through the regrown plug portions into the active region can be decoupled from etched pillar sidewall surfaces.

### BRIEF DESCRIPTION OF THE DRAWINGS

FIG. 1 is a schematic cross-section side view illustration of a partially formed LED with a regrown cladding layer.

FIG. 2 is an isometric view illustration of crystal planes for a Wurtzite crystal structure.

FIG. 3A is a schematic top overlay view illustration of a center trench area and circular pillar structure in accordance with an embodiment.

FIG. 3B is a schematic cross-section side view illustration of a partially formed LED including the circular pillar structure of FIG. 3A with a regrown cladding layer and a center plug in accordance with an embodiment.

FIGS. 4A-4J are schematic cross-section side view illustrations for a sequence of forming a plurality of LEDs with a regrown cladding layer with center plug in accordance with an embodiment.

FIG. 5A is a schematic top overlay view illustration of a plurality of separate trench areas and circular pillar structure in accordance with an embodiment.

FIG. 5B is a schematic cross-section side view illustration of a partially formed LED including the circular pillar structure of FIG. 5A with a regrown cladding layer and a plurality of laterally separate sidewall plugs in accordance with an embodiment.

FIG. 6A is a schematic top overlay view illustration of a plurality of separate trench areas and pillar structure with same facets in accordance with an embodiment.

FIG. 6B is a schematic cross-section side view illustration of a partially formed LED including the structure of FIG. 5A with a regrown cladding layer and a plurality of laterally separate sidewall plugs with same facets as the pillar structure in accordance with an embodiment.

FIG. 7A is a schematic top overlay view illustration of a plurality of separate trench areas and pillar structure with different facets in accordance with an embodiment.

FIG. 7B is a schematic cross-section side view illustration of a partially formed LED including the structure of FIG. 7A with a regrown cladding layer and a plurality of laterally separate sidewall plugs with different facets than the pillar structure in accordance with an embodiment.

FIG. 8A is a schematic top overlay view illustration of a trench area and pillar structure with same facets in accordance with an embodiment.

FIG. 8B is a schematic cross-section side view illustration of a partially formed LED including the structure of FIG. 8A with a regrown cladding layer and a sidewall plug with same facets as the pillar structure in accordance with an embodiment.

FIG. 9A is a schematic top overlay view illustration of a plurality of separate trench areas with angled facets and pillar structure in accordance with an embodiment.

FIG. 9B is a schematic cross-section side view illustration of a partially formed LED including the structure of FIG. 9A with a regrown cladding layer and a plurality of laterally separate sidewall plugs with angled sidewalls in accordance with an embodiment.

FIG. 10A is a schematic top overlay view illustration of a plurality of separate trench areas and pillar structure with different facets in accordance with an embodiment.

FIG. 10B is a schematic cross-section side view illustration of a partially formed LED including the structure of FIG. 10A with a regrown active layer and cladding layer and a plurality of laterally separate sidewall plugs with different facets than the pillar structure in accordance with an embodiment.

### DETAILED DESCRIPTION

Embodiments describe light emitting diode (LED) configurations in which a regrowth plug structure is formed in order to increase sidewall carrier injection to the active layer. In an embodiment an LED includes a base structure including a first cladding layer doped with a first dopant type (e.g. n-type dopant) and a pillar structure protruding from the base structure. The pillar structure may include a mesa structure that includes an active layer with a plurality of quantum well layers, and a second cladding layer that is doped with a second dopant type (e.g. p-type dopant) opposite the first dopant type. In an embodiment the second cladding layer includes a cap portion that wraps across the mesa structure and a plug portion that is laterally adjacent to the plurality of quantum well layers of the mesa structure. In an exemplary fabrication sequence trenches can be etched into the semiconductor stack-up including the first cladding layer and the active layer, resulting in the mesa structures. The second cladding layer is then regrown within the trenches (forming the plug portions) and over the mesa structures (forming the cap portion). In some embodiment the plug portion extends into a center cavity of the mesa structure between mesa exterior sidewalls. In other embodiments multiple plug portions are regrown within laterally separate trenches. Final pillar sidewalls may then be etched through the one or more plug portions.

In one aspect, plug formation allows for increased sidewall injection to the multiple quantum wells. It has been observed with certain materials systems such as GaN/InGaN that the voltage required for operation is significantly higher than the voltage corresponding bandgap from emitting light energy. This is due to strong quantum confined stark effect (QCSE) and high heterojunction barriers, which slow carrier injection in the GaN/InGaN material system.

In another aspect, the cavity formation and plug regrowth allows for specific crystal plane selection of the cavity sidewalls, and regrowth with a high-quality interface.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

In accordance with embodiments, the term “micro” LED as used herein may refer to the descriptive size, e.g. length or width, of the LED. In some embodiments, “micro” LEDs may be on the scale of 0.1 μm to approximately 100 μm or less in many applications. More specifically, in some embodiments, “micro” LEDs may be on the scale of 0.1 μm to 20 μm, such as 10 μm, 5 μm, 3 μm, or 1 μm where the LED lateral dimensions approach or surpass the carrier diffusion length. However, it is to be appreciated that embodiments are not necessarily so limited, and that certain aspects of the embodiments may be applicable to larger, and possibly smaller size scales.

In the following description exemplary processing sequences and structures are described for forming LEDs, which may be micro LEDs. While specific arrangements layers with specific dopant types are described, it is to be appreciated that polarity may be reversed. For example, the relative orientation of p-type or n-type layers or dopant types can be reversed. Additionally reference to an opposite dopant type refers to p-dopant or opposite n-dopant as is common in semiconductor fabrication to achieve primary hole or opposite electron transfer through a semiconductor layer.

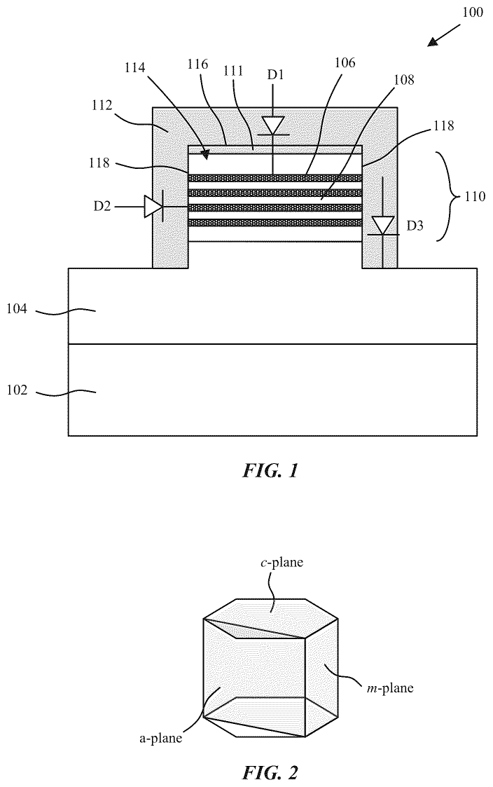

Referring now to FIG. 1, a partially formed LED 100 is illustrated that includes a regrown cladding layer. As shown, the structure includes a growth substrate 102, a first cladding layer 104 of a first dopant type (e.g. n-type), an active layer 110 including a plurality of quantum well layers 106 and barrier layers 108, and a regrown second cladding layer 112 of a second dopant type (e.g. p-type). The second cladding layer may be regrown over a mesa structure 114 etched through the active layer 110. Various additional layers such as buffer layers, confinement layers (e.g. electron and hole blocking layers), spacer layers may be included. For example, the mesa structure 114 may optionally include a buried cladding layer 111 of second dopant type (e.g. p-type) formed over the active layer 110. In such a configuration, the second cladding layer 112 is regrown over the mesa structure 114 including the buried cladding layer 111. In the illustrated configuration carrier injection occurs through diodes D1, D2, D3.

Referring briefly to FIG. 2, several crystal planes for an exemplary Wurtzite crystal structure are shown. A GaN/InGaN system for example has a Wurtzite crystal structure. Growth commonly occurs in the c-plane direction. Thus, the top surface 116 of the mesa structure is a c-plane, and mesa exterior sidewalls 118 may be a-plane or m-plane facets. The c-plane can be characterized as being a polar plane, with the a-plane and m-planes being non-polar. Various other planes are not shown, such as diagonal planes that may be characterized as being semi-polar. It has been observed, and in particular with the GaN/InGaN system, that voltage required for carrier injection is higher in the direction of polar planes than for non-polar planes. Thus, injection voltage required for D1, D3 is higher than D2. This can also result in injection from the second cladding layer through D1 being unevenly distributed in the top quantum well layers and not all quantum well layers. In accordance with embodiments various plug designs are described to mitigate the QCSE and increase carrier injection in the non-polar plane directions across D2 to reduce LED injection voltage requirements and allow for carrier to be uniformly injected into all quantum well layers from the second cladding layer.

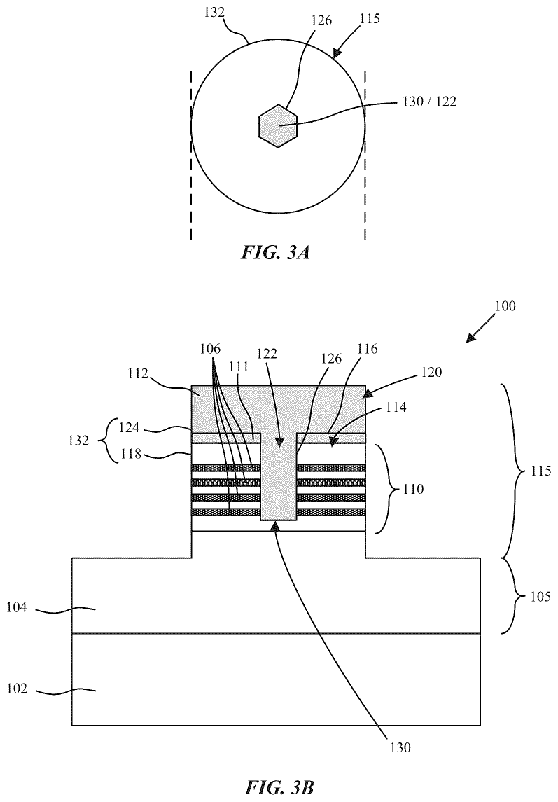

Referring now to FIGS. 3A-3B, FIG. 3A is a schematic top overlay view illustration of a center trench area and circular pillar structure in accordance with an embodiment; FIG. 3B is a schematic cross-section side view illustration of a partially formed LED including the circular pillar structure of FIG. 3A with a regrown cladding layer and a center plug in accordance with an embodiment. As shown, the partially formed LED 100 may be fabricated on a growth substrate 102, and include a base structure 105 and pillar structure 115 protruding from the base structure 105. The base structure may include a first cladding layer 104 doped with a first dopant type (e.g. n-type), and the pillar structure 115 may include a mesa structure 114 and a second cladding layer 112 doped with a second dopant type (e.g. p-type) opposite the first dopant type. The mesa structure 114 may include an active layer 110 with a plurality of quantum well layers 106 and optionally buried cladding layer 111, and the second cladding layer 112 can include a cap portion 120 that wraps across the mesa structure 114 and a plug portion 122 that is laterally adjacent the plurality of quantum well layers 106 of the mesa structure. Specifically, the plug portion 122 can extend into a center cavity 130 of the mesa structure 114 between mesa exterior sidewalls 118. The cavity 130 may have cavity sidewalls 126, which may be shared by the plug portion 122 of the regrown second cladding layer 112. In the particular illustration in FIG. 3A, the plug portion 122 illustrated is overlayed with the outline of the pillar structure 115 pillar sidewalls 132. As shown in FIG. 3B, the LED 100 can include pillar sidewalls 132 spanning the mesa exterior sidewalls 118 and sidewalls 124 of the cap portion 120 of the regrown second cladding layer 112.

In accordance with embodiments described herein carrier injection can be provided to the plurality of quantum well layers 106 by way of the plug portion 122 of the regrown second cladding layer 112, and is not dependent upon the pillar sidewalls 132. In accordance with embodiments, the cavity sidewalls 126, and hence the interface with the plug portion 122, can be formed along non-polar facets of the crystal structure for the active layer 110. Thus, the cavity sidewalls 126 can include primarily m-plane sidewalls of Wurtzite crystal structure, primarily a-plane sidewalls of Wurtzite crystal structure, or a combination thereof. The cavity sidewalls 126 may exhibit a variety of shapes such as hexagon, square, etc. while maintaining facet selection. A hexagon shape for example can be used to provide for only, or primarily, m-plane sidewalls or a-plane sidewalls. Selection of a single plane type may facilitate regrowth crystal quality since scaffolding is not based on multiple different competing planes. The mesa exterior sidewalls 118, and hence the pillar sidewalls 132 can be a variety shapes such as circular, as illustrated, square, hexagon, etc.

It is to be appreciated that while the exemplary embodiments described herein are related to the GaN/InGaN system and Wurtzite crystal structure that embodiments are not limited to such, and can be applicable to a variety of materials systems and crystal structures where LED plug regrowth can be decoupled from pillar sidewall formation.

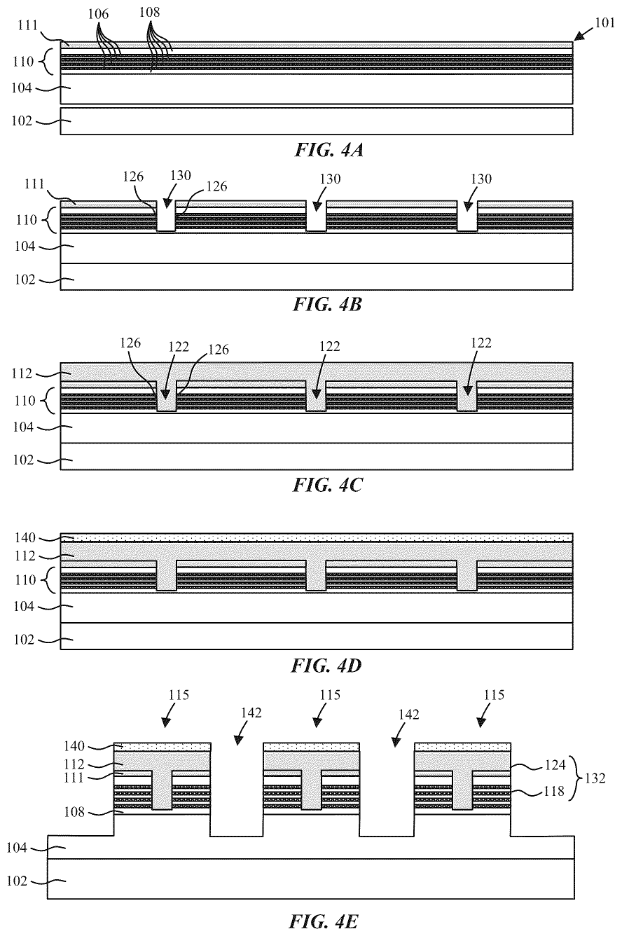

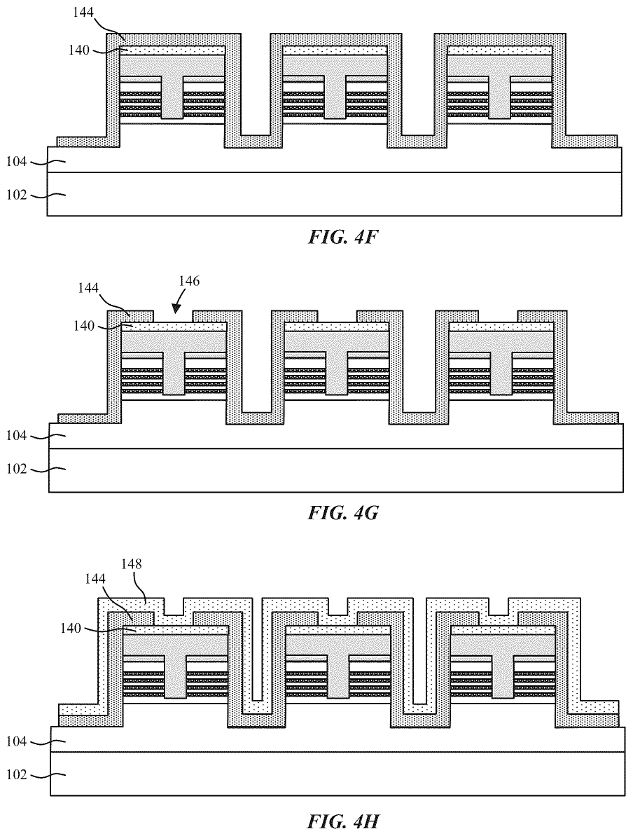

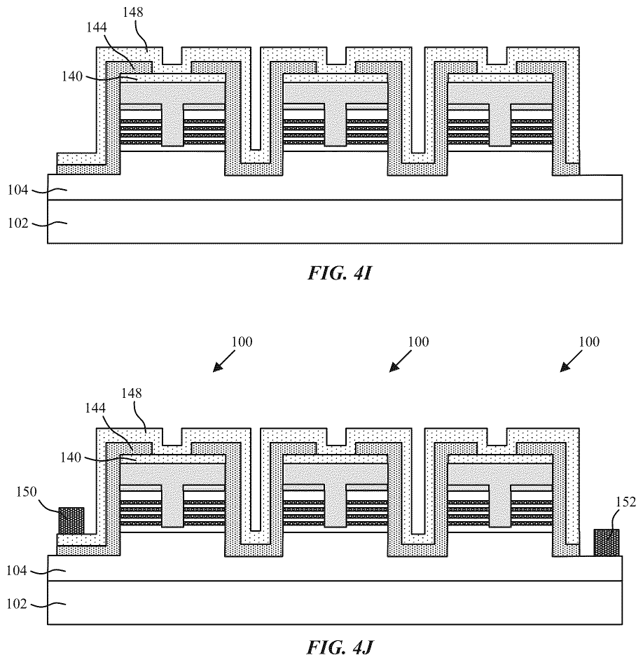

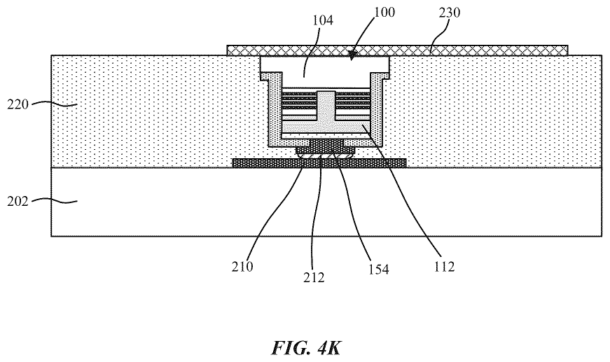

FIGS. 4A-4J are schematic cross-section side view illustrations for a sequence of forming a plurality of LEDs with a regrown cladding layer with center plug in accordance with an embodiment. Referring now to FIG. 4A, a cross-sectional side view illustration is provided of a bulk LED substrate 101 in accordance with an embodiment. The bulk LED substrate 101 structure may be applicable to a variety of compositions and emission spectra. For example, the bulk LED substrate 101 may include III-V nitride materials or III-V phosphide materials and designed for emission of a variety of emission spectra. In a specific embodiment, the bulk LED substrate 101 is based on an GaN/InGaN material system designed for green or blue emission (or even red emission), though could be applicable for a variety of material systems including InP, InGaAlP, InGaAs, GaAs, and AlGaAs.

In one embodiment, formation of the bulk LED substrate 101 begins with the partial formation of a device layer on a growth substrate 102, such as a GaN, sapphire or silicon growth substrate, for example with a thickness of 250-1,000 μm. Growth substrate 102 may optionally be doped, for example with an n-type dopant such as silicon (Si) or tellurium (Te). The multiple layers of the device layer may be grown on the growth substrate 102 using a suitable technique such as metal organic chemical vapor deposition (MOCVD). In order to mitigate lattice mismatch a buffer layer (not illustrated) may first be formed on the growth substrate 102. The buffer layer may include one or more layers. In an exemplary embodiment the buffer layer includes a graded layer. The graded buffer layer for example may be graded from a composition substantially lattice matched to the growth substrate to GaN for example, and may also be doped, for example with an n-type dopant.

A first cladding layer 104 (e.g. n-type cladding layer) is then formed. In the exemplary GaN/InGaN system, the first cladding layer 104 may be formed of GaN. In an embodiment, first cladding layer 104 is doped with a Si dopant concentration of 1×10¹⁸ cm³.

An active layer 110 is then grown on the first cladding layer 104. Active layer 110 may include one or more quantum well (QW) layers or bulk active layers. In an embodiment the one or more quantum well layers 106 or bulk active layers are formed of InGaN, separated by barrier layers 108 formed of GaN. In this aspect, a maximum conduction/valence band offset between quantum wells and barriers is able to confine electrons/holes in the quantum wells.

It is to be appreciated additional layers can optionally be included such as confinement layers (e.g. electron or hole blocking layers), buffer layers, spacer layers, etc. In the illustrated embodiment, an optional buried cladding layer 111 is formed. For example, the exemplary GaN/InGaN system, the buried cladding layer 111 may be formed of GaN, and be p-doped for example, with a Mg dopant concentration of 1×10¹⁸ cm⁻³-1×10¹⁹ cm⁻³, such as 1×10¹⁸ cm⁻³.

Referring now to FIG. 4B, a pattern of cavities 130 is etched into the stack-up and at least to a depth past the quantum well layers 106. For example, the cavity 130 depths may end at a final barrier layer 108, confinement layer, or the first cladding layer 104. In the illustrated embodiment, the cavity 130 depths extend into a lower barrier layer 108, which may also be a confinement layer. In accordance with embodiments, the cavity sidewalls 126 may be selected as non-polar or semi-polar facets or planes. For example, in the exemplary GaN/InGaN system the cavity sidewalls 126 may be formed along non-polar planes such as the m-plane sidewalls of Wurtzite crystal structure and/or a-plane sidewalls of Wurtzite crystal structure. In an embodiment, the cavity sidewalls 126 are formed along sloped semi-polar planes. Etching of the cavities 130 in accordance with embodiments may be performed using dry etching techniques such as deep reactive ion etching (DRIE), wet etching techniques such as potassium hydroxide (KOH), tetramethylammonium hydroxide (TMAH), etc. and combinations thereof. Various cleanings may be performed after etching and prior to regrowth such as KOH, TMAH, sulfuric acid (H₂SO₄), hydrochloric acid (HCl), hydrofluoric acid (HF), etc. to improve the interface quality.

A second cladding layer 112 may then be regrown over the active layer 110 (and optional buried cladding layer 111) and within the cavities 130 as shown in FIG. 4C. In an embodiment, the second cladding layer 112 (e.g. p-type cladding layer) is formed of GaN with a Mg dopant concentration of 1×10¹⁸ cm⁻³-1×10¹⁹ cm³, such as 1×10¹⁸ cm⁻³. In accordance with embodiments, the doped cladding layers 104, 112 may be selected to have a high band gap in order to confine the injected carriers. For example, the doped cladding layers 104, 112 may have a higher bandgap energy than the barrier layers 108. Growth of the second cladding layer 112 may optionally be followed by a planarization operation and deposition of a contact layer 140, such as a conductive oxide, as shown in FIG. 4D. For example, the conductive oxide may be indium tin oxide (ITO), amongst other materials.

Referring now to FIG. 4E trenches 142 are etched into the stack-up to form pillar structures 115 that protrude from the first cladding layer 104. The trenches 142 in accordance with embodiments may effectively separate the micro LEDs being formed from one another. As shown, etching may be partially into the first cladding layer 104, though etching may extend into other layers, such as a confinement layer or spacer layer (not illustrated). Etching of trenches 142 may be formed similarly as etching of the cavities 130 using dry etching techniques such as DRIE, wet etching techniques such as KOH, TMAH, and combinations thereof. Various cleanings may be performed after etching such as KOH, TMAH, H₂SO₄, HCl, HF, etc. to improve the interface quality with the pillar sidewall 132.

Following formation of trenches 142, an insulation layer 144 can be formed as shown in FIG. 4F, for example using a conformal deposition or growth technique such as atomic layer deposition. In an embodiment the insulation layer is formed of a material such as aluminum oxide, though other materials may be used. In an embodiment, insulation layer 144 is between 0-1,000 nm thick, such as 1-100 nm thick, and may have a uniform thickness that conforms to the underlying substrate topography, and forms an outline. The insulation layer 144 may then be patterned to form openings 146 over the pillar structures that expose the contact layer 140.

This may be followed by deposition of a second contact layer 148 such as ITO over the plurality of LEDs and within the openings 146 as shown in FIG. 4H. The second contact layer 148 and insulation layer 144 may then be patterned to expose the first cladding layer 104 (or other layer) as shown in FIG. 4I, followed by formation of first metal contact 150 on the second contact layer 148 and a second metal contact 152 on the first cladding layer 104 (or other layer).

It is to be appreciated that the contact formation of the LEDs 100 is exemplary and embodiments are not so limited. In accordance with embodiments, the array of LEDs 100 could be prepared for wafer bonding to a display substrate, or for intermediate singulation and transfer to a display substrate as coupons (including groups of LEDs), or individually. While the end product illustrated in FIG. 4J illustrates contact layer 140 as a top contact, once transferred to a display substrate the LEDs may be bonded to the display substrate with the pillar structures protruding downward such that contact layer 140 is a bottom contact, for example to a driver pad. The LEDs 100 may not need to be connected in parallel and may have individual contacts. FIG. 4K is a schematic cross-sectional side view illustration of an LED 100 bonded on a display substrate 202 in accordance with an embodiment. As shown, a bonding pad 210 can be formed on the display substrate 202. For example, the bonding pad 210 may be connected to driving circuitry within the display substrate 202. The LED 100 may be bonded to the bonding pad 210 with a bonding material 212 such as a solder material that bonds the bottom conductive contact 154 (e.g. including one or more metal layers) to the bonding pad 210. The LED 100, and for that matter a plurality or array of LEDs, can be encapsulated within an insulation material 220, such as a polymer material. The insulation material may additionally function to hold the LED in place and provide step coverage for the formation of a top electrode layer 230, such as a transparent conductive oxide (TCO) or transparent polymer material to provide electrical connection to the top side of the LED 100. The top electrode layer 230 may be formed directly on the first cladding layer 104, or an intermediate layer such as a top contact layer.

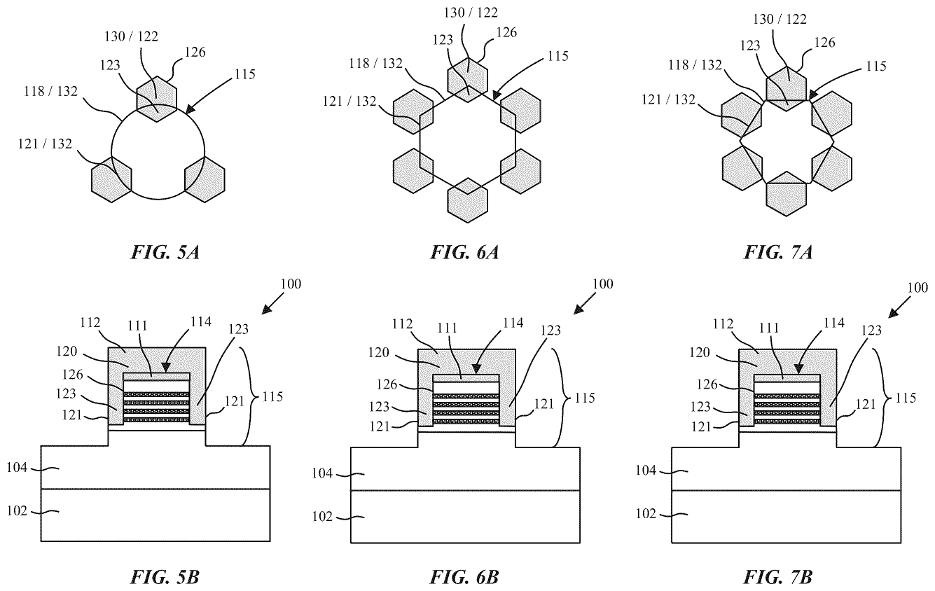

Referring now to FIGS. 5A-5B, FIG. 5A is a schematic top overlay view illustration of a plurality of separate trench areas and circular pillar structure in accordance with an embodiment; FIG. 5B is a schematic cross-section side view illustration of a partially formed LED including the circular pillar structure of FIG. 5A with a regrown cladding layer and a plurality of laterally separate sidewall plugs in accordance with an embodiment. The process sequence for forming the structure of FIGS. 5A-5B is substantially similar to that of FIGS. 4A-4J, with a difference being location of cavities 130, and hence plug portions 122. For example, the bulk LED substrate 101 may be fabricated similarly as with regard to FIGS. 4A-4D, only with location of cavities 130 and plug portions 122 being differently arranged. The cavities 130 and plug portions may still include cavity sidewalls 126 selectively formed along non-polar facets/planes such as primarily a-planes, primarily m-planes, or combinations thereof. In the embodiment illustrated in FIGS. 5A-5B, the pillar structures 115 and pillar sidewalls 132 are etched to partially overlap a plurality of plug portions 122. In this manner, the plug portion 122 in the LED 100 includes a plurality of laterally separate sidewall plugs 123 protruding away from the cap portion 120 and spanning along corresponding cavity sidewalls 126 of the multiple quantum well layers of the active layer 110. The pillar sidewalls 132 can span both portions of the mesa structure 114 mesa exterior sidewalls 118 as well as plug exterior sidewalls 121 shared by the cap portion 120 and the plurality of laterally separate sidewall plugs 123.

In accordance with multiple embodiments described herein the plurality of laterally separate sidewall plugs 123 are physically separate from one another in order evenly spread injection voltage around the active layer. This can mitigate the potential for carrier accumulation at a specific point, and provide consistency across LED 100 manufacture.

Referring now to FIGS. 6A-6B, FIG. 6A is a schematic top overlay view illustration of a plurality of separate trench areas and pillar structure with same facets in accordance with an embodiment; FIG. 6B is a schematic cross-section side view illustration of a partially formed LED including the structure of FIG. 5A with a regrown cladding layer and a plurality of laterally separate sidewall plugs with same facets as the pillar structure in accordance with an embodiment. The particular embodiment illustrated in FIGS. 6A-6B is substantially similar to that illustrated in FIGS. 5A-5B with one difference being the pattern of the pillar structure 115 pillar sidewalls 132, as well as number of cavities 130 formed. In the particular embodiment illustrated, the pillar sidewalls 132 can share the same crystal planes as the cavity sidewalls 126. For example, both may be m-plane facets/sidewalls. As shown in FIGS. 6A-6B, the plurality of laterally separate sidewall plugs 123 formed as a result of etching the pillar structure 115 are arranged at the corners of a hexagon mesa structure 114. In such a configuration the pillar sidewalls 132 span the mesa exterior sidewalls 118, and the plug exterior sidewalls 121 of the plurality of separate sidewall plugs 123. In an embodiment, the pillar sidewalls 132 are primarily m-plane sidewalls of Wurtzite crystal structure.

Referring now to FIGS. 7A-7B, another LED 100 variation is illustrated that is substantially similar to that of FIGS. 6A-6B with one difference being orientation of the pillar structure 115 pillar sidewalls 132, which can be formed along a different crystal plane than the cavity sidewalls 126. Thus, by rotating the pillar structure 115 by 90 degrees, the pillar sidewalls 132 can be primarily a-plane sidewalls of Wurtzite crystal structure. In an embodiment, the pillar sidewalls 132 span the mesa exterior sidewalls 118 as well as the plug exterior sidewalls 121 of the plurality of separate sidewall plugs 123. In this configuration the plurality of separate sidewall plugs 123 are formed on the sidewalls of the mesa structure 114 rather than at the corners of the mesa structure 114 from FIGS. 6A-6B.

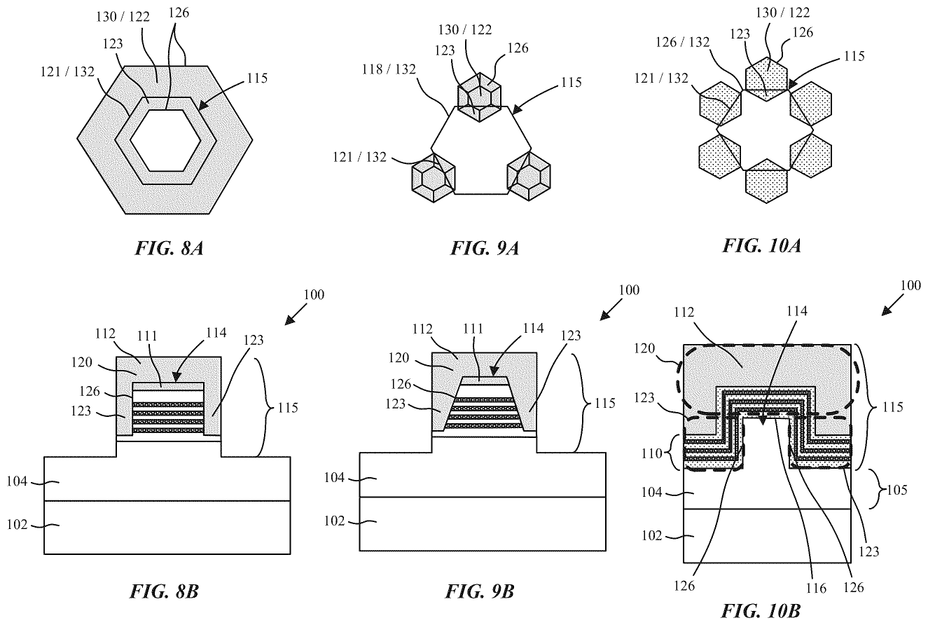

Referring now to FIGS. 8A-8B, FIG. 8A is a schematic top overlay view illustration of a trench area and pillar structure with same facets in accordance with an embodiment; FIG. 8B is a schematic cross-section side view illustration of a partially formed LED including the structure of FIG. 8A with a regrown cladding layer and a sidewall plug with same facets as the pillar structure in accordance with an embodiment. The embodiment illustrated in FIGS. 8A-8B differs from other embodiments in that a single cavity 130 is formed for the LED 100, followed by etching of the pillar sidewalls 132 in the same pattern as the cavity sidewalls 126. In this manner, a single sidewall plug 123 is formed around the mesa structure 114, with the same facets along a non-polar plane such as a-plane or m-plane. It is to be appreciated however that the pillar sidewalls 132 do not necessarily need to match the cavity sidewalls 126, and may have different shapes such as square, circular, etc. and be formed along different crystal planes than the cavity sidewalls 126.

Cavities 130 and plug regrowth can also be formed along semi-polar planes. Referring to FIGS. 9A-9B, FIG. 9A is a schematic top overlay view illustration of a plurality of separate trench areas with angled facets and pillar structure in accordance with an embodiment; FIG. 9B is a schematic cross-section side view illustration of a partially formed LED including the structure of FIG. 9A with a regrown cladding layer and a plurality of laterally separate sidewall plugs with angled sidewalls in accordance with an embodiment. The embodiment illustrated in FIGS. 9A-9B is substantially similar to that illustrated and described with regard to FIGS. 7A-7B, with a difference being that the cavities 130 are etched along semi-polar facets to form cavity sidewalls 126 that are angled. The cavities 130 and regrown plug portions 122 need not necessarily be hexagonal, and may assume different configurations. Furthermore, the number of plug portions and area occupation can be variable to tune quantum well layer emission. In the illustrated embodiment the pillar sidewalls 132 are shown as being etched along a non-polar plane such as a-plane or m-plane, though this is exemplary. The pillar sidewalls 132 can be formed along a mixture of a-plane and m-plane, and may also be formed along semi-polar planes. In an embodiment, the cavity sidewalls 126 are primarily angled semi-polar sidewalls of Wurtzite crystal structure, and the pillar sidewalls 132 span mesa exterior sidewalls and plug exterior sidewalls of the plurality of separate sidewall plugs 123. For example, the pillar sidewalls 132 may be primarily a-plane sidewalls of Wurtzite crystal structure, m-plane sidewalls of Wurtzite crystal structure, or a combination thereof.

Until this point embodiments have been described in which cavity 130 patterning is performed after formation of the active layer 110. However, trench pattering can be performed prior to formation of the active layer 110 so that the active layer 110 is not etched prior to regrowth. Referring now to FIGS. 10A-10B, FIG. 10A is a schematic top overlay view illustration of a plurality of separate trench areas and pillar structure with different facets in accordance with an embodiment; FIG. 10B is a schematic cross-section side view illustration of a partially formed LED including the structure of FIG. 10A with a regrown active layer and cladding layer and a plurality of laterally separate sidewall plugs with different facets than the pillar structure in accordance with an embodiment. The process sequence is substantially similar to previous embodiments, except that during the initial growth only first cladding layer 104 is formed, and cavities 130 are etched though the first cladding layer 104, followed by cleaning, and regrowth of the active layer 110 and second cladding layer 112. In such an embodiment, it has been observed that indium incorporation into the quantum well layers is weak along the non-polar sidewalls (e.g. the vertical portions of the quantum well layers). In this manner, these quantum well layers do not prevent lateral carrier injection, and holes can be injected laterally thorough the shallow quantum wells layers (closest the second cladding layer 112), and then drop into the deeper quantum well layers on top of the mesa structure 114 and recombine there with electrons.

In an embodiment an LED 100 includes a base structure including a first cladding layer 104 doped with a first dopant type (e.g. n-type), and a pillar structure 115 protruding from the base structure. The pillar structure 115 in this embodiment includes a mesa structure 114 formed of the first cladding layer 104, and a regrowth structure including a cap portion 120 that wraps across the mesa structure and a plug portion 122 laterally adjacent cavity sidewalls 126 of the mesa structure. The mesa structure 114 can include a top surface 116 and cavity sidewalls 126 extending from the base structure 105 to the top surface 116. The regrowth structure can include an active layer 110 that includes a plurality of quantum well layers and a second cladding layer 112. The active layer spans the base structure, the cavity sidewalls 126, and the top surface 116, and the second cladding layer 112 spans over the active layer 110. Similar to previous plug characterizations, the plug portion 122 can include a plurality of laterally separate sidewall plugs 123 spanning along corresponding cavity sidewalls 126 of the mesa structure. In an embodiment, the cavity sidewalls 126 are primarily m-plane sidewalls of Wurtzite crystal structure, a-plane sidewalls of Wurtzite crystal structure, or combinations thereof. The pillar sidewalls 132 in such an embodiment may span exterior sidewalls of the first cladding layer 104 the plurality of laterally separate sidewall plugs 123.

In utilizing the various aspects of the embodiments, it would become apparent to one skilled in the art that combinations or variations of the above embodiments are possible for forming micro LEDs with regrown plug structures. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A light emitting diode comprising:
a base structure including a first cladding layer doped with a first dopant type;
a pillar structure protruding from the base structure, the pillar structure comprising:
a mesa structure including an active layer that includes a plurality of quantum well layers; and
a second cladding layer doped with a second dopant type opposite the first dopant type, wherein the second cladding layer includes a cap portion that wraps across the mesa structure and a plug portion laterally adjacent the plurality of quantum well layers of the mesa structure.

2. The light emitting diode of claim 1, wherein the plug portion extends into a center cavity of the mesa structure between mesa exterior sidewalls.

3. The light emitting diode of claim 2, further comprising pillar sidewalls spanning the mesa exterior sidewalls and sidewalls of the cap portion of the second cladding layer.

4. The light emitting diode of claim 3, further comprising an insulation layer spanning the pillar sidewalls and across the cap portion.

5. The light emitting diode of claim 4, further comprising a contact opening in the insulation layer adjacent to the cap portion, and a contact layer within the contact opening.

6. The light emitting diode of claim 2, wherein the center cavity includes primarily a-plane sidewalls of Wurtzite crystal structure.

7. The light emitting diode of claim 2, wherein the center cavity includes primarily m-plane sidewalls of Wurtzite crystal structure, primarily a-plane sidewalls of Wurtzite crystal structure, or a combination thereof.

8. The light emitting diode of claim 2, wherein the center cavity includes primarily m-plane sidewalls of Wurtzite crystal structure.

9. The light emitting diode of claim 8, wherein the mesa exterior sidewalls are a combination of m-plane sidewalls of Wurtzite crystal structure and a-plane sidewalls of Wurtzite crystal structure.

10. The light emitting diode of claim 8, wherein the mesa exterior sidewalls are circular.

11. The light emitting diode of claim 1, wherein the plug portion includes a plurality of laterally separate sidewall plugs protruding away from the cap portion and spanning along corresponding cavity sidewalls of the plurality of quantum well layers.

12. The light emitting diode of claim 11, wherein the cavity sidewalls are primarily m-plane sidewalls of Wurtzite crystal structure.

13. The light emitting diode of claim 12, further comprising pillar sidewalls spanning mesa exterior sidewalls and plug exterior sidewalls of the plurality of separate sidewall plugs, wherein the pillar sidewalls are primarily a-plane sidewalls of Wurtzite crystal structure.

14. The light emitting diode of claim 12, further comprising pillar sidewalls spanning mesa exterior sidewalls and plug exterior sidewalls of the plurality of separate sidewall plugs, wherein the pillar sidewalls are primarily m-plane sidewalls of Wurtzite crystal structure.

15. The light emitting diode of claim 11, wherein the cavity sidewalls are primarily angled semi-polar sidewalls of Wurtzite crystal structure.

16. The light emitting diode of claim 15, further comprising pillar sidewalls spanning mesa exterior sidewalls and plug exterior sidewalls of the plurality of separate sidewall plugs, wherein the pillar sidewalls are primarily a-plane sidewalls of Wurtzite crystal structure, m-plane sidewalls of Wurtzite crystal structure, or a combination thereof.

17. A light emitting diode comprising:
a base structure including a first cladding layer doped with a first dopant type;
a pillar structure protruding from the base structure, the pillar structure comprising:
a mesa structure formed of the first cladding layer, the mesa structure including a top surface and cavity sidewalls extending from the base structure to the top surface;
a regrowth structure including a cap portion that wraps across the mesa structure and a plug portion laterally adjacent cavity sidewalls of the mesa structure;
wherein the regrowth structure includes:
an active layer that includes a plurality of quantum well layers, wherein the active layer wraps spans the base structure, the cavity sidewalls, and the top surface; and
a second cladding layer doped with a second dopant type opposite the first dopant type, wherein the second cladding layer spans over the active layer.

18. The light emitting diode of claim 17, wherein the plug portion includes a plurality of laterally separate sidewall plugs spanning along corresponding cavity sidewalls the mesa structure.

19. The light emitting diode of claim 18, wherein the cavity sidewalls are primarily m-plane sidewalls of Wurtzite crystal structure, a-plane sidewalls of Wurtzite crystal structure, or combinations thereof.

20. The light emitting diode of claim 19, further comprising pillar sidewalls spanning exterior sidewalls of the first cladding layer and the plurality of laterally separate sidewall plugs.
